(19) United States
(12) Patent Application Publication
(10) Pub. No.: US 2025/0071166 A1
(43) Pub. Date: Feb. 27, 2025

(54) METHOD FOR ESTABLISHING COMMUNICATION BETWEEN A FIRST DIGITAL TWIN AND A SECOND DIGITIAL TWIN

(71) Applicant: Endress+Hauser Process Solutions AG, Reinach (CH)

(72) Inventors: Michael Riester, March (DE); Jörg Reinkensmeier, Steinen (DE); Oliver Simon Hansert, Bad Säckingen (DE)

(21) Appl. No.: 18/720,982

(22) PCT Filed: Nov. 28, 2022
(86) PCT No.: PCT/EP2022/083466

§ 371 Date: Jun. 17, 2024

(30) Foreign Application Priority Data
Dec. 21, 2021 (DE) 10 2021 134 182.5

(51) Int. Cl. H04L 67/02; G06F 30/20

(52) U.S. Cl. CPC H04L 67/02; G06F 30/20

(57) ABSTRACT

Establishing communication between first and second digital twins, a first REST-based API assigned to the first digital twin and a second REST-based API assigned to the second digital twin includes transmitting a request to an endpoint of the first API and receiving a response therefrom, and transmitting a request to an endpoint of the second API and receiving a response therefrom. The responses are compared and analyzed. A mapping model is created on the basis of the comparing and analyzing, the mapping model containing semantic and technical requirements of the first API and of the second API. The mapping model is used for mutual communication between the first digital twin and the second digital twin, the mapping model translating a data transfer from one of the two digital twins in a manner conforming to the technical and semantic requirements of the API of the other of the two digital twins.

The invention relates to a method for establishing communication between a first digital twin and a second digital twin, a first REST-based API being assigned to the first digital twin and a second REST-based API being assigned to the second digital twin.

Automation components that are used in industrial installations are already known from the prior art. For example, field devices are used as automation components used in process automation technology as well as in manufacturing automation technology. In principle, all devices which are process-oriented and which supply or process process-relevant information are referred to as field devices. Field devices are thus used for detecting and/or influencing process variables. Measuring devices, or sensors, are used for detecting process variables. These are used, for example, for pressure and temperature measurement, conductivity measurement, flow measurement, pH measurement, fill level measurement etc., and detect the corresponding process variables of pressure, temperature, conductivity, pH value, fill level, flow etc. Actuators are used for influencing process variables. These are, for example, pumps or valves that can influence the flow of a fluid in a pipe or the fill level in a tank. In addition to the aforementioned field devices, automation components are also understood to include gateways, edge devices, remote I/Os, radio adapters, or, generally, devices that are arranged at the field level.

A multitude of such automation components is produced and marketed by the Endress+Hauser group.

In modern industrial plants, field devices are usually connected to superordinate units via communication networks such as fieldbuses (Profibus®, Foundation® Fieldbus, HART® etc.). Usually, the superordinate units are control systems (DCS) or control units, such as an SPC (stored program control). The superordinate units are used for, among other things, process control, process visualization, and process monitoring, as well as commissioning of the field devices. The measured values recorded by the field devices, especially by sensors, are transmitted via the respective bus system to a (or in some cases a plurality of) superordinate unit(s). In addition, data transmission from the superordinate unit via the bus system to the field devices is also required, especially for configuration and parameterization of field devices and for controlling actuators.

In the course of Industry 4.0 or IIoT (“Industrial Internet of Things”), the data generated by the field devices are also frequently collected directly from the field by means of what are known as data conversion units, which are referred to as “edge devices” or “cloud gateways,” for example, and are transmitted automatically to a central cloud-enabled database (also referred to simply as “cloud”) on which one or more applications are located. These applications, which, for example, offer functions for visualizing and further processing the data stored on the database, can be accessed by a user by means of the Internet.

It is provided for each of the automation components in the system to have a digital twin. A digital twin, also referred to as a digital image, is a virtual representation of the automation component which has the identical configuration, parameter values, current device status, algorithms, etc. of the automation component. The digital twin thus has all relevant properties of the automation component which fully describe the automation component for its intended purpose. It is provided for the automation component and the digital twin to be always identical in terms of the relevant properties. A change in the properties of the automation component leads to synchronization (via Industry 4.0 or IIoT techniques), so that the properties of the digital twin are updated accordingly.

However, digital twins exist not only for automation components, but can be created for any physical or digital object. For example, it is also provided for applications (software programs), which are executed, for example, by a cloud, to have an associated digital twin, which fully describes the respective application with regard to its function.

As of today, there is hence a wide variety of digital twin types. They predominantly have non-standardized interfaces. Communication between such digital twins requires great effort as regards the mapping, i.e., the method of making the data provided by an interface accessible to the other interface in terms of format and semantics. Maintenance of this mapping must be performed manually. Updates, e.g., firmware updates on the side of the automation component, must therefore also be performed in the corresponding interface. It is not sufficient that the second digital twin interfaces are, for example, REST-based, but they must also share the same semantics.

In light of this problem, the invention is based on the object of providing a method which allows mutual communication of two digital twins that do not know each other.

The object is achieved by a method for establishing communication between a first digital twin and a second digital twin, a first REST-based API being assigned to the first digital twin and a second REST-based API being assigned to the second digital twin, comprising:
transmitting a request to at least one endpoint of the first API and receiving at least one response of the first API;
transmitting a request to at least one endpoint of the second API and receiving at least one response of the second API;
comparing and analyzing the at least one response of the first API with the at least one response of the second API);
creating at least one mapping model on the basis of the comparing and analyzing, the mapping model containing semantic and technical requirements of the first API and of the second API; and
using the mapping model for mutual communication between the first digital twin and the second digital twin, the mapping model translating a data transfer from one of the two digital twins in a manner conforming to the technical and semantic requirements of the API of the other of the two digital twins.

The method according to the invention thus allows for carrying out a mapping between the two digital twins for mutual communication. Both APIs learn the semantics and format of the responses and/or of the expected inputs at the endpoints. The mapping model formed therefrom is henceforth used as a kind of interpreter between the first digital twin and the second digital twin.

REST (“representative state transfer”) represents a uniform concept of a software architecture of distributed systems, in particular web services.

An API (“application programming interface”) is an interface that allows applications to communicate with one another. A REST-based API is thus an API built on the REST architecture and used in particular for machine-to-machine communication. Using such a REST-based API makes it possible to request information from an application, e.g., by means of an HTTP-request. The HTTP-request is directed to dedicated endpoints of the APIs.

Put simply, an endpoint is the one end of a communication channel. When an API interacts with another system, the contact points of this communication are considered to be endpoints. An API consists of a plurality of endpoints that can be addressed. There are types of endpoints which can be requested by means of a request (“GET”, “READ”, etc.) and output information as a response. The response has an API-specific technology, logic, and semantics. Other types of endpoints can receive commands (“PUT”, “WRITE”, etc.), which allow a value to be written or set into the application associated with the API. The command must correspond to the predefined API-specific technology, logic, and semantics.

It may be provided for the mapping model to control communication between more than two digital twins. The method according to the invention can thereby be applied to any number of digital twins.

According to an advantageous embodiment of the method according to the invention, it is provided for at least one list of at least some of all the endpoints of the first API and the second API to be created by reading out the corresponding first API or second API. The respective API is thus requested and, in response to the request, delivers the endpoints which are requested later in the method according to the invention.

An advantageous embodiment of the method according to the invention provides for the response of the first API and/or the second API to include an additional piece of information which is also used for the steps of comparing and analyzing. The additional information, referred to also as “payload,” can be, for example, additional information provided by the corresponding digital twin. For example, if a digital twin relates to an automation component, the additional information can contain, for example, diagnostic or status data, in particular as a string.

An advantageous embodiment of the method according to the invention provides for a cloud application to be used for the steps of comparing, analyzing, and creating the mapping model. The cloud application thus accesses the APIs of both digital twins and makes the corresponding requests regarding to the available endpoints. The cloud application can advantageously be a so-called “API mapper” or a communication broker.

Here, it is provided for an AI algorithm to be used for the steps of comparing, analyzing, and creating the mapping model. The AI algorithm is trained with corresponding training data and trained to recognize patterns or known structures in the responses received from the APIs in order to be able to identify the functioning, structure, and semantics of the respective endpoints.

For the steps of comparing, analyzing, and creating the mapping model, the AI algorithm preferably accesses additional information of an instance assigned or assignable to the cloud application, the instance being a classification model, in particular based on ECLASS, or a continuously expandable database containing a plurality of further mapping models and assigned responses from further APIs.

It can be furthermore provided for the AI algorithm to update the created mapping model in the event that the instance has new additional information. Viewed over time, the mapping model is thus continuously refined so that its accuracy and reliability is increased.

According to an advantageous embodiment of the method according to the invention, it is provided to use first API and/or second API for transmitting the request and to use a web service for receiving the corresponding response. A web service is a machine-to-machine communication standard used by the cloud application that accesses the respective APIs.

According to a first advantageous variant of the method according to the invention, it is provided for the first digital twin to relate to a first field device of the automation component.

In an advantageous embodiment of the first variant of the method according to the invention, it is provided for the second digital twin to relate to a second automation component, or wherein the second digital twin relates to an application, in particular to a cloud application.

According to a second advantageous variant of the method according to the invention, it is provided for the first digital twin to relate to a first application, in particular to a cloud application, and wherein the second digital twin relates to a second application, in particular to a cloud application.

Examples of automation components, in particular field devices and network devices such as gateways, edge devices, etc., have already been listed by way of example in the introductory part of the description.

An application, referred to also as application software, is a computer program executing functions which do not relate to the system on which they are executed. Such an application does not necessarily have to be executed by a cloud, but can in principle run on any system or host as long as the latter can establish a connection with its digital twin. The system or host can thus be a server, a PC, a mobile terminal (smartphone, tablet, etc.) or the like.

The invention is explained in greater detail with reference to the following FIGURE, In which

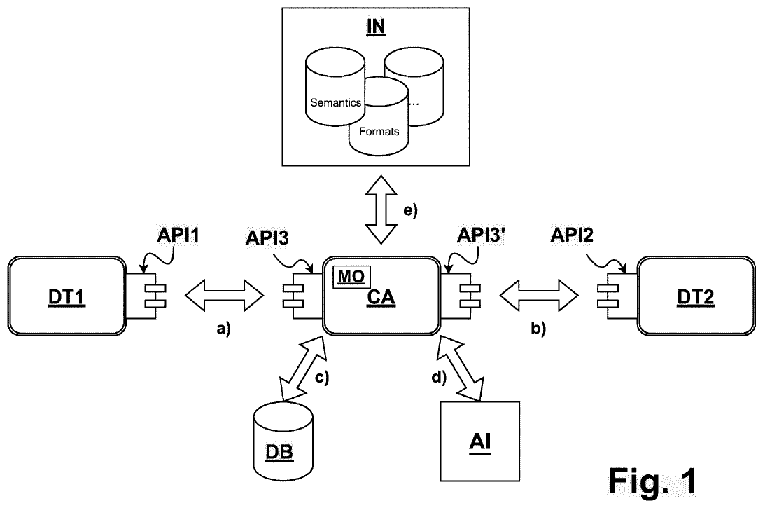

FIG. 1: shows an exemplary embodiment of the method according to the invention.

FIG. 1 shows an exemplary embodiment of the method according to the invention. Two digital twins DT1, DT2 are provided for this purpose. The digital twins DT1, DT2 are located on a cloud or server and are contactable by Internet. In the present example, the first digital twin DT1 relates to an automation component, more precisely a to field device in the form of a temperature sensor. The second digital twin DT2 relates to a further automation component, more precisely to a field device in the form of a temperature sensor from a different manufacturer.

For communication with the digital twins DT1, DT2, a REST-based API1, API2 API is assigned to each digital twin DT1, DT2. Both API1, API2 APIs differ in terms of the structure and semantics of the expected commands, or data output, so that they cannot readily communicate with one another.

A cloud application CA is used to establish mutual communication. The cloud application CA can communicate with the API1, API2 APIs of the digital twins DT1, DT2 by means of web services.

In an upstream method step, the cloud application CA transmits a request to both API1, API2 APIs with the request to transfer all endpoints (“GET”, “READ”, etc.), on the basis of which a requesting party can obtain data of the corresponding temperature sensor, as well as those endpoints (“PUT”, “WRITE”, etc.), on the basis of which commands can be transmitted. The API1, API2 APIs then provide lists of the corresponding endpoints to the cloud application CA.

In a first method step a), the cloud application CA specifically queries the individual endpoints of the AP1 API of the first digital twin DT1. For example, the following endpoint can be requested:
“GET_SENSOR_DATE (Device-ID)”

The API1 API returns the following first character string as a response:
“23D65H2, 36.43, 16-12-2021 13:32:09, OK”

In a second method step b), the cloud application CA specifically queries the individual endpoints of the API2 API of the first digital twin DT2. For example, the following endpoint can be requested:
“READ_Data (Device-ID-Vendor ID)”

The API2 API returns the following second character string as a response:
“F43G456, 33xx, 35.56, 1, OK, 3F7, 16.13.35 2021/12/16”

The two character strings are stored. Then, in method steps c) to e), several instances and/or methods are used sequentially or simultaneously. An AI algorithm (step d)) is thus used, in particular based on machine learning, which analyzes the individual character strings and analyzes the semantics and form of the responses in order to create a mapping model MO. Such a mapping model MO contains the technology, form, and semantics of the two API1, API2 APIs, or their individual endpoints, and allows a mutual transmission of messages to one another, corresponding to the requirements of API1, API2 APIs.

One or more already existing mapping models which are stored in a database DB can be accessed (method step c)). Recognized patterns in the character string can be identified and interpreted on the basis of additional information which is stored in an external instance IN (for example ECLASS classifications).

The mapping model MO is present upon completion of the analysis. The mapping model MO lists the individual formats and semantics of the endpoints of both API1, API2 APIs.

The endpoint of the API1 API of the first digital twin DT1 requested in this example, which output the first character string as a response, follows the following structure:

“Device ID, Measured Value (PV), Timestamp, Device Status”.

The endpoint of the API2 API of the second digital twin DT2 requested in this example, which output the second character string as a response, follows the following structure:
“Device ID, Vendor ID, Measured Value (PV), Temperature_UNIT, Health-Status_IO-Link_Master, Timestamp”

The mapping model MO furthermore includes an assignment of both API1, API2 APIs of the digital twins DT1, DT2 to one another, so that a communication interface is created between the digital twins DT1, DT2 on a technical and semantic level. It is detected, for example, that both mentioned endpoints basically allow for the same statement to be made about the respective temperature sensor.

It is also determined that the structure and semantics of both endpoints are similar, but do not have quite the same number of transfer and output parameters. The syntax for the timestamp is also different. API 1 uses the “DD-MM-YYYY HH:ii:ss” format, whereas REST-API 2 uses the following notation: “hh.ii.ss YYYY/mm/dd”.

While REST-API 2 uses the “Temperature_UNIT” parameter to indicate, for example, whether the measured value is “degrees Celsius” or “Fahrenheit”, no equivalent parameter is found in the endpoint of API1.

However, API1 of the first digital twin DT1 offers yet another endpoint:
“GET_ALL_DEVICE_CONFIGURATION_VALUES”

The current setting for the temperature value is also contained therein.

All this must now be taught to API2 API of the second digital twin DT2 (“teach-in”). This means that it must understood the semantics and logical structure of the API1 of the first digital twin DT1. In case of doubt, “dummy” or “default values” would have to be generated in order to be able to carry out a method of the respective other API if the corresponding values are not present.

For example, the API2 API of the second digital twin DT2 requests the health status of the connected IO-Link master. However, this value may not be known at all. A dummy value is therefore generated which stands for “Device OK.”

All these rules and assignments are contained in the mapping model MO. The mapping model MO can thus be considered as a kind of interpreter between the two digital twins DT1, DT2.

A third digital twin (not shown) is introduced as an example of communication of the digital twins.

Said third digital twin relates to a temperature controller. By means of the method according to the invention, the API of this digital twin is requested and the semantics and form of the following endpoint are determined:
“WRITE_INPUTS”

This endpoint allows target and actual values to be written into the temperature controller. The temperature controller expects a character string in the following form:
“Device-ID, Role (“Target Value, Actual Value, Control Deviation”), Actual Value, Temperature_UNIT, Timestamp”

The mapping model MO now contains an assignment of the first and second digital twins DT1, DT2 to the third digital twin. A control loop can thus be established, for example. For this purpose, the third digital twin according to the above-mentioned endpoint requires the target values of the temperature sensors assigned to the digital twins DT1, DT2. They are each contained in the expressions “Measured Value (PV)” of the respective endpoints. The mapping model MO now identifies all the expressions (Device-ID, “Target Value”, etc.) required by the endpoint of the API of the third twin, identifies the corresponding values in the endpoints of the two API1, API2 APIs and creates a corresponding character string that is transmitted to the “WRITE_INPUTS” endpoint of the API of the third digital twin. The character string can be processed directly, since it has the correct format and semantics.

In an alternative example, the second digital twin DT2 relates to a further cloud application, for example to an asset management system. This system expects periodic updates of the device status of the temperature sensor, which is assigned to the first digital twin DT1. The mapping model allows, on the one hand, for the device status requests of the second digital twin to be prepared according to the requirements of the respective endpoint of the API1. On the other hand, the response of the endpoint of the API1 API of the first digital twin is processed by means of the mapping model MO such that it meets the requirements of the corresponding endpoint (for example a “PUT_DATA” command) and that the device status can be stored correctly in the further cloud application.

### LIST OF REFERENCE SIGNS

a), b), . . . , d) method steps
API1 first REST-based API
API2 second REST-based API
CA cloud application
DB database
DT1 first digital twin
DT2 second digital twin
IN instance
AI AI algorithm
MO mapping model

1-11. (canceled)

12. A method for establishing communication between a first digital twin and a second digital twin, a first REST-based API being assigned to the first digital twin and a second REST-based API being assigned to the second digital twin, comprising:
transmitting a request to at least one endpoint of the first API and receiving at least one response of the first API;
transmitting a request to at least one endpoint of the second API and receiving at least one response of the second API;
comparing and analyzing the at least one response of the first API with the at least one response of the second API;
creating at least one mapping model on the basis of the comparing and analyzing, the mapping model containing semantic and technical requirements of the first API and of the second API; and
using the mapping model for mutual communication between the first digital twin and the second digital twin, the mapping model translating a data transfer from one of the two digital twins in a manner conforming to the technical and semantic requirements of the API of the other of the two digital twins.

13. The method according to claim 12, with at least one list of at least some of all the endpoints of the first API and the second API being created by reading out the corresponding first API or second API.

14. The method according to claim 12, the response of the first API and/or the second API including an additional piece of information which is also used for the steps of comparing and analyzing.

15. The method according to claim 12, the steps of comparing, analyzing, and creating the mapping model being performed by a cloud application.

16. The method according to claim 15, with the cloud application using an AI algorithm for the steps of comparing, analyzing, and creating the mapping model.

17. The method according to claim 16, with the AI algorithm accessing additional information of an instance assigned or assignable to the cloud application for the steps of comparing, analyzing, and creating the mapping model, the instance being a classification model.

18. The method according to claim 17, with the AI algorithm updating the created mapping model in the event that the instance has new additional information.

19. The method according claim 12, wherein the first API and/or second API are being used for transmitting the request and a web service being used for receiving the corresponding response.

20. The method according to claim 12, the first digital twin relating to a first automation component.

21. The method according to claim 20, the second digital twin relating to a second automation component, or the second digital twin relating to an application.

22. The method according to 12, the first digital twin relating to a first application, in particular to a cloud application, and the second digital twin relating to a second application.
